(19) United States
(12) Patent Application Publication
(10) Pub. No.: US 2008/0067667 A1
(43) Pub. Date: Mar. 20, 2008

(54) Semiconductor device with a semiconductor chip stack and plastic housing, and methods for producing the same

(75) Inventors: Joachim Mahler, Regensburg (DE); Stefan Landau, Wehrheim (DE); Eduard Knauer, Regensburg (DE); Khalil Hosseini, Weihmichl (DE); Manfred Mengel, Bad Abbach (DE)

Correspondence Address: EDELL , SHAPIRO & FINNAN , LLC, 1901 RESEARCH BOULEVARD , SUITE 400, ROCKVILLE, MD, 20850, US

(73) Assignee: INFINEON TECHNOLOGIES AG, Neubiberg (DE)

(21) Appl. No.: 11/755,035

(22) Filed: May 30, 2007

(30) Foreign Application Priority Data
Jun. 1, 2006 (DE) 102006026023.6

(51) Int. Cl. H01L 23/08; H01L 21/56

(52) U.S. Cl. 257/702; 438/109; 257/E23.192; 257/E21.502

(57) ABSTRACT

The invention relates to a semiconductor device (1) comprising a semiconductor chip stack (2) and a plastic housing (3), and to methods for producing the semiconductor device (1). The semiconductor device (1) is constructed on a device carrier (4), on which a first semiconductor chip (5) is fixed by its rear side (6). At least one second semiconductor chip (8) is adhesively bonded by its rear side (9) on the top side (7) of the first semiconductor chip (5) by means of an adhesive layer (10). A second plastic composition (17) is arranged between a first plastic housing composition (11) of the plastic housing (3) and the edge sides (12, 13) of the adhesive layer and the edge sides (14, 15) of the second semiconductor chip (8) and also the top side (16) of the second semiconductor chip (8) in such a way that the first plastic housing composition (11) has no physical contact with the second semiconductor chip (8) and with the adhesive layer (10).

The invention relates to a semiconductor device comprising a semiconductor chip stack and a plastic housing, and to methods for producing the semiconductor device. The semiconductor device is constructed on a device carrier, on which a first semiconductor chip is fixed by its rear side. At least one second semiconductor chip is adhesively bonded by its rear side on the top side of the first semiconductor chip by means of an adhesive layer.

### BACKGROUND

A semiconductor device of this type is known from the document US 2004/0163843 A1. In this case, the known semiconductor component comprising a semiconductor chip stack not only has at least two semiconductor chips that are adhesively bonded vertically one on top of another and are enclosed by a first plastic housing composition, but additionally has a compliant element of a second plastic composition that is arranged on an interface between the at least two semiconductor chips and the first plastic housing composition, the compliant element being more elastic and more flexible than the first plastic housing composition. Said compliant element is arranged either on individual edge sides of the first semiconductor chip and of the second semiconductor chip or all around one or both semiconductor chips or on the top side of the semiconductor chip stack.

The compliant element is intended to reduce deformations and warpages of the two semiconductor chips on account of different coefficients of thermal expansion between the first plastic housing composition and the semiconductor chips. Furthermore, the compliant element is intended to enable horizontal and/or vertical expansions of the first plastic housing composition relative to the semiconductor chip stack without loading or damaging the semiconductor chip stack. Elastomers or epoxy resins having rubber-elastic properties are proposed as compliant elements, wherein the elastomers have polyimides, polyketones, polyetherketones, polyethersulfones, polyethylene terephthalates, fluoroethylene-propylene copolymers, cellulose, triacetates, silicones or rubber. Although the compliant element and the first plastic housing composition can both be composed of epoxy resin, they differ in that the first plastic housing composition has a filler which makes the first plastic housing composition fireproof and stabler, while the epoxy resin for the compliant element has plasticizers that support the elasticity and the compliance.

Said compliant element, which is arranged either on the edge sides or on the top side of the semiconductor chip stack, nevertheless does not solve the problems posed by the MSL test (moisture sensitivity level) for electronic devices, which test has been required as revised standard IPC/JEDEC J-STD-020-C since July 2004. During this moisture test, in particular in the case of semiconductor devices comprising a chip stack in which the semiconductor chips are held together by means of an adhesive layer, delamination problems occur which have still not been solved by the compliant element known in the document US 2004/0163843 A1. Besides the problem of the penetration of moisture molecules and moisture ions into the adhesive layers, it has also been shown that an additional delamination occurs between interfaces of the second semiconductor chip of the semiconductor chip stack and the first plastic housing composition during the required MSL tests.

In a typical MSL test of version C—revised since July 2004—of the abovementioned JEDEC standard, said MSL test includes storage of the electronic devices under conditions of high moisture for a week. This is followed by three soldering simulations in a conventional soldering melting furnace with a temperature profile that is defined exactly for the housing surface temperature. The devices are then inspected and tested electrically. Afterward, an ultrasonic scanning microscope is used to check whether the inner adhesion areas of the plastic housing and specifically the surface of the semiconductor chips to the first plastic housing composition and also the contact layers of the wire bonding have delaminated. It is thus possible to draw conclusions about the service life of the semiconductor devices and about the aging of the boundary layer adhesion of the first plastic housing composition.

The MSL test and the soldering temperature simulations are part of a first step of a semiconductor device qualification process in order to ensure that the semiconductor device reliably withstands a soldering process conducted by the customer. The guaranteed maximum soldering temperature and the MSL level are either marked on the device housing and/or available as data on request. For semiconductor device housings having a thickness of less than 1.6 mm, peak soldering temperatures of the J-020C standard of 260° C. are prescribed, in which case the device body can encompass a volume ranging from the smallest possible volume to more than 2000 mm³. Said 260° C. are additionally prescribed for device housings having a thickness of between 1.6 mm and 2.5 mm and a device volume of less than 350 mm³. In the case of housing thicknesses of more than 2.5 mm and larger volumes, the prescribed peak temperatures for the triple soldering temperature test that takes place after the MSL test are between 245° C. and 250° C. This test may be followed by even further temperature cycle tests in order to obtain statements about the reliability of semiconductor devices.

In the case of a combination of MSL test, a triple cycle with a maximum soldering temperature of 260° C. and a hundred-fold thermocycle test between −50° C. and +150° C., it has been ascertained in the case of power semiconductor devices that conventional semiconductor devices comprising semiconductor chip stacks tend toward delaminations of adhesive layers and also to a delamination between a first plastic housing composition and interfaces with the stacked second semiconductor chip.

### SUMMARY

It is an object of the invention to specify a semiconductor device which, under the test conditions specified above, in particular during the standardized MSL test according to J-020-C, 2004, and subsequent soldering temperature test at peak temperatures of 260° C. and also during subsequent temperature cycle tests, achieves a higher reliability than displayed previously by semiconductor devices comprising a semiconductor chip stack.

This object is achieved by means of the subject matter of the independent claims. Advantageous developments of the invention emerge from the dependent claims.

The invention specifies a semiconductor device comprising a semiconductor chip stack and a plastic housing, and methods for producing the semiconductor device. For this purpose, the semiconductor device is constructed on a device carrier, on which a first semiconductor chip is fixed by its rear side. At least one second semiconductor chip is adhesively bonded by its rear side on the top side of the first semiconductor chip by means of an adhesive layer. A second plastic composition is arranged between a first plastic housing composition of the plastic housing and the edge sides of the adhesive layer and also the edge sides of the second semiconductor chip and the top side of the second semiconductor chip in such a way that the first plastic housing composition has no physical contact with the second semiconductor chip and with the adhesive layer.

Such a semiconductor device comprising a semiconductor chip stack whose second semiconductor chip and whose adhesive layer have an encapsulating second plastic composition has the advantage that during the prescribed storage in a moist area, the moisture molecules and moisture ions cannot penetrate along the interfaces between the second semiconductor chip and the first plastic housing composition or between the second semiconductor chip and the adhesive layer since the edge sides of the adhesive layer and also the edge sides of the second semiconductor chip and the top side thereof are encapsulated by the second plastic composition, which practically seals the sensitive interfaces and protects them from the ingress of moisture.

At the same time, said second plastic composition for encapsulating or for embedding the second semiconductor chip with the adhesive layer serves for withstanding the required peak temperatures for the simulation of a soldering process. That is to say that the thermal stability and thus the softening point of the second plastic composition lie above the simulation soldering temperature for the soldering test, such that a material having a softening point of greater than or equal to 270° C. is preferably used for the second plastic composition. In order to avoid a delamination between the second plastic composition and the first plastic housing composition embedding it from the outset, a material having a high surface activity in particular with respect to the first plastic housing composition is used for the second plastic composition, such that a high adhesion to the first plastic housing composition proceeds from the second plastic composition.

In one embodiment, the edge sides of the first semiconductor chip are not encapsulated by the second plastic composition. The edge sides of the first semi-conductor chip are in physical contact with the first plastic housing composition. Consequently, the second plastic composition is only arranged on the second upper semiconductor chip and the edge sides of the adhesive layer.

In one preferred embodiment of the invention, the first semiconductor chip is soldered by its rear side on the device carrier rather than being adhesively bonded thereon as in the prior art cited above, such that here the problem of delamination cannot actually occur as long as a solder material is used which has a sufficient thermal stability and thus withstands the simulation soldering tests at 260° C. according to the above revised JEDEC standard J-020-C of 2004. What are particularly advantageously suitable for this are eutectic solder compounds such as occur between gold and aluminum layers, the aluminum layer being applied on the rear side of the first semiconductor chip and the gold layer being applied on the device carrier, or diffusion solder layers that form high-temperature-resistant intermetallic phases. Consequently, not only the adhesive layers between the semiconductor chips but also the interfaces between the stacked semiconductor chip and the first plastic housing composition are a risk which, however, is solved by the high-temperature-resistant second plastic composition according to the invention which encapsulates and/or embeds the critical interfaces.

In one preferred embodiment of the invention, the second semiconductor chip to be stacked is smaller than the first semiconductor chip. This has the advantage that edge regions of the top side of the first semiconductor chip remain free, on which edge regions it is possible to arrange contact areas of the first semiconductor chip for connecting elements to the device carrier and to the second semiconductor chip, especially as said contact areas are not covered by the second semiconductor chip.

In one preferred embodiment of the invention, the semiconductor device has connecting elements between the semiconductor chips among one another and/or between the semiconductor chip stack and the device carrier. In this case, a wide variety of combinations can be implemented, such that, by way of example, for supply lines, the first semiconductor chip is connected to the device carrier by means of correspondingly thick aluminum bonding wires and, for corresponding signal connections between the first semiconductor chip and the second semiconductor chip, thin gold bonding wires are arranged as signal connections. It is also possible to connect the second semiconductor chip to contact pads on the device carrier by means of corresponding bonding wires.

In a further embodiment of the invention, not only are the second semiconductor chip and the first plastic housing composition protected from the ingress of moisture by a second plastic composition, but the connecting elements are also surrounded by the plastic composition in such a way that the first plastic housing composition has no physical contact with the connecting elements. This embodiment of the invention has the advantage that the second plastic composition does not have to be applied selectively to the second semiconductor chip and to the edge sides of the plastic layer, rather the second plastic composition can be applied in a simple manner, e.g. by dipping the semiconductor chip stack with connecting elements or by spraying on the second plastic composition onto the semiconductor chip stack with connecting elements without complicated selectivity.

In this case, in an advantageous manner, the second plastic composition can form an encapsulation of the second semiconductor chip and the adhesive layer or the second semiconductor chip and the adhesive layer and also parts of the connecting elements can be embedded into the plastic composition. Embedding has the advantage that the second plastic composition can be applied on the second semiconductor chip by simple dispensing, such that the entire semiconductor chip and parts of the top side of the first semiconductor chip and also parts of the connecting elements are embedded in the second plastic composition. In this case, an advantageous embodiment of the invention arises in which the second plastic composition partly covers the edge regions of the top side of the first semiconductor chip, preferably in the region of contact areas for the connecting elements.

A polymer having a high thermal stability, great surface activity and hydrophobic properties is preferably used as second plastic composition. Both thermoplastics and thermosetting plastics can be used for the second plastic composition, provided that they have the high thermal stability and the great surface activity including a moisture-repellent property. Besides the known polyamide and epoxy resins, but with high thermal stability and great surface activity, in particular phenolic resins, amino resins and/or a polyester resin having a high thermal stability and great surface activity are suitable as enveloping second plastic layer and/or as embedding second plastic composition. Furthermore, it is also possible to use temperature-resistant liquid crystalline polymers, provided that they have the required thermal stability and the great surface activity. Further preferred second plastic compositions have a modified silane polymer or a polybenzoxazole, a polybenzimidazole, a polyisocyanate and/or a polyurethane having a high thermal stability and great surface activity.

If the second plastic composition is used as a closed plastic casing at least for the second semiconductor chip and the adhesive layer, then the plastic casing has a casing thickness d_{H} of between a few 100 nanometers and a few millimeters, preferably between 0.5 μm≦d_{H}≦2000 μm. In a further embodiment of the invention, the first semiconductor chip has a power semiconductor component and the second semiconductor chip has a sensor component. The semiconductor device preferably has a TO220 housing type for this purpose. However, the solution according to the invention can also be used for other housing types such as a BGA housing type (ball grid array).

A method for producing a semiconductor device comprising a semiconductor chip stack has the following method steps. The first step involves producing a device carrier with contact pads for connecting elements and for a first semiconductor chip on the top side of the device carrier and external contact areas on the underside of the device carrier. Afterward, a first semiconductor chip is fixed on a contact pad of the device carrier, which is also called a chip pad. A semiconductor chip to be stacked is then arranged on the top side of the first semiconductor chip by means of an adhesive layer. Afterward, it is possible to fit connecting elements between the semiconductor chips and/or between the semiconductor chip stack and the device carrier. Finally, at least the edge sides of the adhesive layer and the edge sides of the second semiconductor chip and also the top side of the second semiconductor chip are encapsulated with a temperature-resistant second plastic composition. Finally, a first plastic housing composition is applied with embedding of the encapsulated semiconductor chip stack and the connecting elements on the device carrier whilst leaving free the external contacts on the underside of the device carrier.

This method has the advantage that a semiconductor device is created in the case of which a moisture-resistant semiconductor device that is resistant to high soldering temperatures is created by the combination of two plastic compositions having different functions. The moisture resistance is ensured by the second plastic composition, which directly protects the second semiconductor chip and the adhesive layer, while the first plastic housing composition with its filler particles forms a stable contour of the plastic housing.

A method for producing a plurality of semiconductor devices by means of a leadframe has the following method steps. The first step involves producing different semiconductor wafers for the first semiconductor chips and for the second semiconductor chips to be stacked with a plurality of semiconductor chip positions on the semiconductor wafers, wherein the semiconductor chip positions on the top side of the semiconductor wafer have contact areas for connecting elements. The semiconductor wafer is subsequently separated into individual first semiconductor chips and individual second semiconductor chips to be stacked.

Furthermore, a leadframe with a plurality of semiconductor device positions is produced, wherein semiconductor device carriers with leads and contact pads for connecting elements and also with external contact areas and with chip carriers for semiconductor chip stacks are arranged in the semiconductor device positions. On the chip carriers of the leadframe, in the semiconductor device positions, firstly the first semiconductor chips are fixed and then the second semiconductor chips to be stacked are adhesively bonded on said first semiconductor chips by means of adhesive layers.

Afterward, in each of the semiconductor device positions, it is possible to fit connecting elements between the semiconductor chips among one another and the contact pads of leads of the leadframe. Finally, the edge sides of the adhesive layers and the edge sides of the second semiconductor chips and also the top sides of the second semiconductor chips are encapsulated with a temperature-resistant second plastic composition. This is followed by application of a first plastic housing composition in the semiconductor device positions of the leadframe with embedding of the encapsulated semiconductor chip stacks and the connecting elements and with external contact areas of the leads of the leadframe being left free. Finally, the leadframe is separated into individual semiconductor components, after which the edge sides of the semiconductor device and the underside of the semiconductor device have external contact areas.

A method of this type has the advantage that a plurality of semiconductor components arise simultaneously and that protection for the second semiconductor chips and protection for the adhesive layers of the second semiconductor chips arise as a result of selective application of a second plastic composition, which is different from the first plastic housing composition, in the semiconductor device positions of the leadframe.

In a further method for producing a plurality of semiconductor devices, a panel is used instead of a leadframe, said panel having device carriers in the form of wiring substrates in a plurality of semiconductor device positions. Since a panel of this type has an insulating substrate plate which has, on its top side and/or on its underside, corresponding wiring structures and between them through contacts leading through the substrate plate, a plurality of semiconductor devices can be constructed on the basis of a panel of this type, wherein the first semiconductor chips and the semiconductor chips to be stacked are once again produced from semiconductor wafers. The first semiconductor chips and the second semiconductor chips to be stacked are not stacked on chip carriers, then, but rather on corresponding contact pads of the wiring structure of the substrate plate which has the device carriers.

The production of the semiconductor chip stacks and the fitting of the connecting elements is once again followed by an encapsulation of at least the edge sides of the adhesive layers and the edge sides of the second semiconductor chips and also the top sides of the second semiconductor chips with a temperature-resistant second plastic composition. Said temperature-resistant second plastic composition differs from the first plastic housing composition in that it has a hydrophobic surface and has a high surface activity besides the thermal stability, such that there is improved adhesion to the second semiconductor chip and to the adhesive layer and, at the same time, high adhesion to the first plastic housing composition is also ensured. A first plastic housing composition is then applied to the substrate plate with encapsulated semiconductor chip stack and connecting elements, which first plastic housing composition embeds the encapsulated semiconductor chip stack and the connecting elements in such a way that a composite plate arises which is then subsequently divided into individual semiconductor devices by separating the panel.

This method has the advantage that once again a multiplicity of semiconductor devices according to the invention can be produced simultaneously. In one preferred exemplary implementation of the method, the first semiconductor chip is fixed by its rear side on the device carrier cohesively by soldering thereon, diffusion soldering and/or by alloying thereon. In this case, a solder connection is achieved which is temperature-resistant above 260° C., especially as the soldering temperature simulations are to be carried out at temperatures of 260° C.

In one embodiment, during the encapsulation of the edge sides of the adhesive layers and of the second semiconductor chip with the second plastic composition, the edge sides of the first semiconductor chip are kept free of the second plastic composition. These edge sides of the second semiconductor chip are encapsulated with the first plastic composition and are in physical contact with said first plastic housing composition.

The semiconductor chip to be stacked is adhesively bonded by its rear side onto the top side of the first semiconductor chip, such that the contact areas arranged on the top side of the semiconductor chip to be stacked remain freely accessible for fitting connecting elements. During the fitting of the connecting elements, between the semiconductor chips signal bonding wires preferably composed of gold wire are bonded onto corresponding contact areas of the semiconductor chips. For fitting connecting elements between the first semiconductor chip and the contact pads of the device carrier, aluminum bonding wires are bonded for current supply purposes and gold bonding wires are bonded for signal transmission purposes. Copper bonding wires or copper bonding tapes have also proved worthwhile for supplying first semiconductor chips with high currents.

For encapsulating the second semiconductor chip and also the edge sides of the adhesive layer, the second plastic composition is sprayed on, spun on or applied by means of dipping into a plastic bath with subsequent drying and curing. In this case, use is preferably made of a second plastic composition which can simultaneously be patterned photolithographically in order to free the surfaces of the temperature-resistant second plastic composition as far as required. On the other hand, it is also possible, particularly in the case of spraying on, to use a stencil in order to protect the surfaces which are not intended to be coated against the application of the temperature-resistant second plastic composition.

Finally, the second plastic composition can also be applied by jet printing, in a manner similar to that in the case of an inkjet printer, such that a selective application of the second plastic composition can be applied selectively on the provided edge sides of the adhesive layer and the edge sides of the second semiconductor chip and also on the surface thereof. One of the abovementioned thermoplastics or thermosetting plastics, in particular of the abovementioned polymers, is used as second plastic composition, and so a repetition of the appropriate materials is unnecessary. However, it should be pointed out that mixtures of the abovementioned materials and also copolymers of the abovementioned materials can be used for the second plastic layer.

### BRIEF DESCRIPTION OF THE DRAWINGS

The invention will now be explained in more detail with reference to the accompanying figures.

FIG. 1 shows a schematic cross section of a semiconductor device with semiconductor chip stack and a boundary layer at risk of delamination;

FIG. 2 shows a schematic cross section of the semiconductor component in accordance with FIG. 1 with further boundary layers at risk of delamination;

FIG. 3 shows a schematic cross section of a semiconductor device with encapsulating plastic layer composed of a second plastic composition in accordance with a first embodiment of the invention;

FIG. 4 shows a schematic cross section of a semiconductor device with an embedding second plastic composition in accordance with a second embodiment of the invention;

FIG. 5 shows a schematic cross section of a semiconductor device in accordance with a third embodiment of the invention.

### DETAILED DESCRIPTION

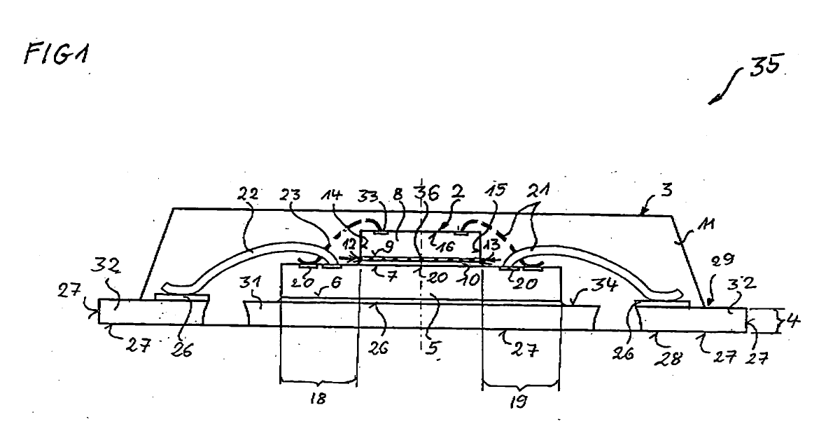

FIG. 1 shows a schematic cross section of a semiconductor device 35 with semiconductor chip stack 2 and a boundary layer 36 at risk of delamination if such a semiconductor device 35 is subjected to an MSL test (moisture sensitivity level test) for one week in a moist area and a subsequent, preferably triple, soldering simulation test at a peak temperature of 260° C. and subsequent thermal cyclic loadings with 100 temperature cycles between −50° C. and +150° C. In this case, the H₂O water molecules, which are significantly smaller than the large O₂ oxygen molecules of the dry air, and in particular the even smaller OH⁻¹ ions and H⁺ hydrogen ions creep along the boundary layers between device carrier 31 with applied semiconductor chip areas of the semiconductor chips 5 and 8 and the first plastic housing composition 11 of the plastic housing 3 through to the boundary layer 36 (identified by dots) at risk of delamination between an adhesive layer 10 and the rear side 9—to be connected cohesively—of the second semiconductor chip 8 to be stacked with the top side 7 of a first semiconductor chip 5 of the semi-conductor chip stack 2. In this case, the moisture molecules and ions penetrate into the boundary layer 36 at risk of delamination via the edge sides 12 and 13 of the adhesive layer 10.

The moisture molecules and ions of the water vapor that have penetrated into the semiconductor devices to be tested during the one week moist area storage modified according to JEDEC standard, 2004 J/020-C, said molecules and ions being significantly smaller than the oxygen molecules of the dry air, ensure during the subsequent soldering simulation steps and temperature cycle test steps that a delamination that is clearly discernable in an ultrasonic microscope occurs along the line—identified by dots—of the boundary layer 36 at risk of delamination between the adhesive layer 10 and the semiconductor chips 5 and 8 of the semiconductor chip stack 2.

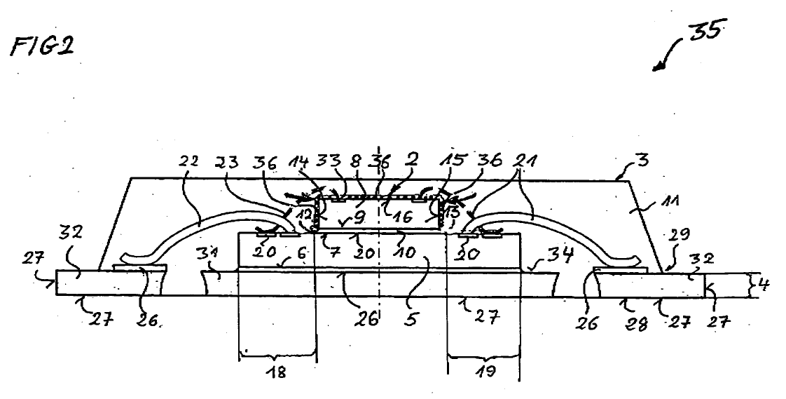

FIG. 2 shows a schematic cross section of the semiconductor component 35 in accordance with FIG. 1 with further boundary layers 36 at risk of delamination. Since the moisture molecules and moisture ions also creep along the edge sides 14 and 15 and the top side 16 of the stacked second semiconductor chip 8, further boundary layers 36 at risk of delamination arise, said boundary layers being identified by dots in FIG. 2, between the plastic housing composition 11 and the edge sides 14 and 15 of the stacked second semiconductor chip 8 and also the top side 16 thereof.

While the first semiconductor chip 5 of the semiconductor device 35 as shown in this test example is fixed by a rear side 6 on a chip carrier 31 by means of a soft solder connection, or a eutectic solder connection and/or a diffusion solder connection, which is jeopardized to a lesser extent by the water molecules or water ions and also the hydrogen molecules, such moist molecules and ions have a particularly serious effect as causes of delamination for the adhesive layer 10 and the second semiconductor chip 8 with its semiconductor chip areas that is arranged on the adhesive layer 10. Moreover, by means of a shaping of the chip carrier 31, a positively locking connection is produced between the first plastic housing composition 11 and the chip carrier 31 with first semiconductor chip 5 soldered thereon, which connection is less at risk of delamination, even if moisture molecules and ions penetrate into the boundary layers, than the stacked second semiconductor chip with its interfaces with the first plastic housing composition 11.

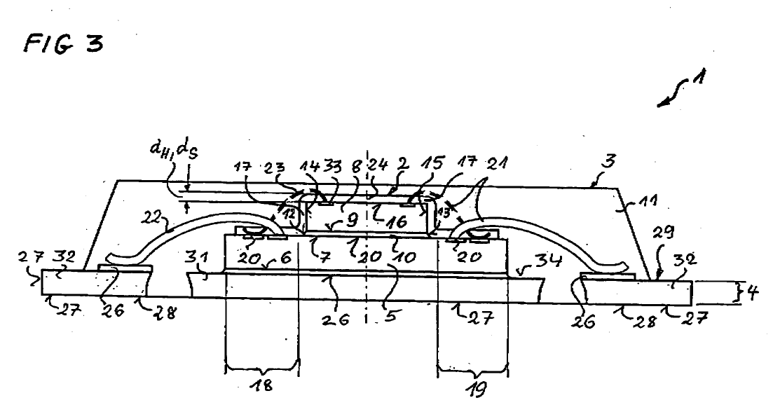

FIG. 3 shows a schematic cross section of a semiconductor device 1 with encapsulating plastic layer 24 composed of a second plastic composition 17 in accordance with one embodiment of the invention. For this purpose, an encapsulating plastic layer 24 composed of a second plastic composition 17 is applied prior to the application of the first plastic housing composition 11 and after the fitting of connecting elements 21 in the form of aluminum bonding wires 22 and/or gold bonding wires 23 between the stacked semi-conductor chips 5 and 8 among one another or between the semiconductor chip stack 2 and contact pads 26 on, for example, leads 32 of a leadframe 29. Said encapsulating plastic layer 24 has a second plastic composition 17, which completely protects the edge sides 12 and 13 of the adhesive layer 10 and the edge sides 14 and 15 of the stacked second semiconductor chip 8 and also the top side 16 of the second semiconductor chip 8 with its contact areas 33 against moisture attacks with subsequent temperature solder loading tests and thermal cyclic loading tests. The edge sides of the first semiconductor chip 5 are not encapsulated by the second plastic composition 17 and are in contact with the first plastic housing composition 11.

This reduces both the risk of delamination between the stacked second semiconductor chip 8 and its surfaces with respect to the first plastic housing composition 11 and the risk of delamination between adhesive layer 10 and stacked second semiconductor chip 8. For such a protective encapsulation in the form of a second plastic composition 17 that forms an encapsulating plastic layer 24, it is possible to use second plastic compositions having corresponding thermal stability above 260° C. and suitable high surface activity which ensure a good adhesion on the second semiconductor chip 8 and on the adhesive layer 10 and to the first plastic housing composition 11 of the plastic housing 3.

For this purpose, plastics from the polymer classes polyimides, polybenzoxazoles, polybenzimidazoles, polyisocyanates, polyurethanes, liquid crystalline polymers, high-temperature-resistant thermoplastics and/or thermosetting plastics in the form of epoxides, phenols, unsaturated polyesters or amino resins are preferably used as second plastic composition. Modified silane polymers and silicones and also copolymers having at least one of the aforementioned components, and also mixtures of the abovementioned polymers can also be contained in the second plastic composition.

The following advantages are thereby achieved:

1. an increase in the adhesive strength and the reliability of the adhesive layer 10,

2. an increase in the adhesive strength between the first plastic housing composition 11 and the stacked second semiconductor chip 8,

3. protection and physical decoupling of the adhesively bonded second semiconductor chip 8 from the top side 7 of the first semiconductor chip with respect to mechanical and predominantly dynamically mechanical stresses in the plastic housing 3 which are induced by the first plastic housing composition 11, which has a significantly higher coefficient of thermal expansion than the semiconductor chip stack.

4. The application of the above encapsulating protective layer composed of second plastic composition 17 results in a significant increase in the bonding area of the second semiconductor chip 8 to the first semiconductor chip 5, such that given constant housing stress as a result of the plastic housing composition 11, this thermally induced stress acts on an enlarged adhesive area and the shear forces are thus advantageously reduced as a result of the stress being distributed over a larger area.

5. Protection of the bonding connecting wires against mechanical damage can also be improved in particular at the critical locations of the transition from contact areas 20 of the first semiconductor chip 5 and also contact areas 33 of the second semiconductor chip 8 to the bonding wires 22 and 23, respectively.

For this purpose, use is made of an encapsulating plastic layer 24 composed of the second plastic composition 17 with a casing thickness d_{H} of between 0.5 μm≦d_{H}≦2000 μm, an encapsulating plastic layer 24 preferably having a thickness d_{S} of between 0.5 μm≦d_{S}≦100 μm. The thickness range d_{M} of between 100 μm≦d_{M}≦2000 μm is shown in the subsequent second exemplary embodiment of the semiconductor component with the subsequent figure.

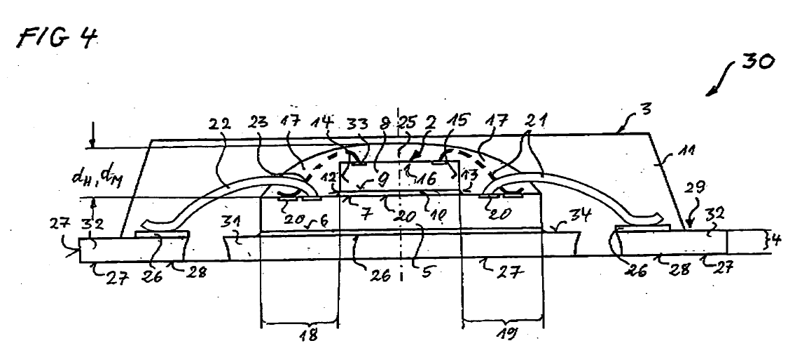

FIG. 4 shows a schematic cross section of a semiconductor device 30 with embedding second plastic composition 25 in accordance with a second embodiment of the invention. Components having the same functions as in FIG. 3 are identified by the same reference symbols and are not discussed separately. In this second exemplary embodiment of the semiconductor device 30, too, the semiconductor chip stack 2 is arranged on a top side 34 of a device carrier 4, which in this case has a chip carrier 31. On the underside 28 of the semiconductor device 30 there are arranged freely accessible external contact areas 27 composed of lead ends 32 with external contact areas 27 likewise on the edge sides of the severed lead ends 32.

The difference with respect to the first embodiment of the invention in accordance with FIG. 3 consists in the fact that a thin plastic layer for protection of the critical interfaces at risk of delamination is not applied to the top side 7 with the contact areas 20 of the first semiconductor chip 5, rather an embedding plastic composition 25 composed of the same materials as mentioned above is applied with a thickness d_{M} of between 100 μm≦d_{M}≦2000 μm. This protective cap composed of the second plastic composition 17 having a suitable thermal stability above 260° C. and a softening point of greater than or equal to 270° C., a high surface activity and suitable hydrophobic properties protects, then, not only the adhesive layer 10 and the jeopardized areas of the second semiconductor chip 8 but also the edge regions 18 and 19 of the top side 7 of the first semiconductor chip 5 with the bonding connections both of the signal bonding wires 23 preferably composed of a gold alloy and of the thicker aluminum bonding wires 22 for a current supply of the first semiconductor chip 5.

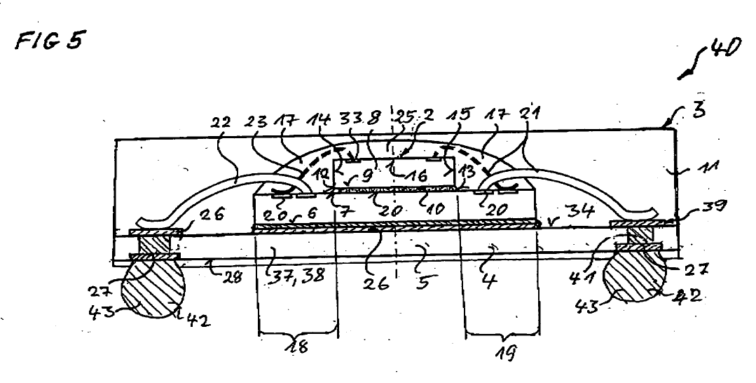

FIG. 5 shows a schematic cross section of a semiconductor device 40 in accordance with a third embodiment of the invention. Components having the same functions as in the previous figures are identified by the same reference symbols and are not discussed separately. This third embodiment of the invention has a BGA housing type, in the case of which the device carrier 4 is constructed from a substrate plate 37 of a panel 38, the panel 38 having a plurality of device carriers 4 as substrate plate 37 and a wiring structure 39 of the substrate plate 37 being arranged on the top side 34 of the device carrier 4. The top side of the substrate plate 37 has contact pads 26 for the connecting elements 21 and a large-area contact pad 26 for the semiconductor chip stack 2. Through contacts 41 through the substrate plate 37 connect the contact pads 26 to external contact areas 27 on which are arranged, in this case, solder balls 42 as external contacts 43.

The solution shown in FIG. 4 of an embedding second plastic composition 25 for protecting the first semiconductor chip 8 and its adhesive layer 10 was chosen for this third embodiment of the invention. At the same time, the edge regions 18 and 19 of the top side 7 of the first semiconductor chip 5 with the contact areas 20 for the bonding connections 22 and 23 are also protected against delamination as a result of an MSL test with subsequent triple soldering temperature simulation and further at least 100 thermal cyclic loadings. FIG. 5 is furthermore intended to illustrate that the basic idea according to the invention is suitable practically independently of the various housing types in order to protect semiconductor devices appertaining to power electronics against delamination of interfaces on account of the test conditions mentioned above.

1. A semiconductor device, comprising:
an adhesive layer;
a first plastic housing composition;
a chip stack including a first semiconductor chip fixed by its rear side on the device carrier and at least one second semiconductor chip adhesively bonded by its rear side on the top side of the first semiconductor chip via the adhesive layer; and
a second plastic composition arranged between the first plastic housing composition and edge sides of the adhesive layer and the top side and edge sides of the at least one second semiconductor chip;
wherein the first plastic housing composition has no physical contact with the second semiconductor chip and with the adhesive layer.

2. The semiconductor device according to claim 1, wherein the second semiconductor chip is smaller than the first semiconductor chip.

3. The semiconductor device according to claim 1, wherein the first semiconductor chip includes a plurality of contact areas disposed in at least one edge region of the top side of the first semiconductor chip (5), wherein the at least one edge region is not covered by the second semiconductor chip.

4. The semiconductor device, according to claim 1, further comprising:
first connecting elements connecting the first semiconductor chip to the at least one second semiconductor chip; and the device carrier.

5. The semiconductor device according to claim 4, wherein:
the first connecting elements comprise gold bonding wires; and
the second connecting elements comprise aluminum bonding wires.

6. The semiconductor device according to claim 4, wherein the second plastic composition is arranged between the first connecting elements and the first plastic housing composition, wherein the first plastic housing composition is not in physical contact with the first connecting elements.

7. The semiconductor device according to claim 1, wherein the second plastic composition is a plastic layer that encapsulates the second semiconductor chip and the adhesive layer.

8. The semiconductor device according to claim 1, wherein the second plastic composition is an embedding second plastic composition.

9. The semiconductor device according to claim 3, wherein the second plastic composition partly covers the at least one edge region of the top side of the first semiconductor chip at least in the region of the plurality of the contact areas.

10. The semiconductor device according to claim 1, wherein the second plastic composition comprises a polymer having a high thermal stability and great surface activity.

11. The semiconductor device as claimed according to claim 1, wherein the second plastic composition comprises a thermoplastic or a thermosetting plastic having a high thermal stability and great surface activity.

12. The semiconductor device according to claim 1, wherein the second plastic composition comprises a polyimide having a high thermal stability and great surface activity.

13. The semiconductor device according to claim 1, wherein the second plastic composition comprises a phenolic resin, an amino resin and/or a polyester resin having a high thermal stability and great surface activity.

14. The semiconductor device according to claim 1, wherein the second plastic composition comprises a liquid crystalline polymer having a high thermal stability and great surface activity.

15. The semiconductor device according to claim 1, wherein the second plastic composition comprises a modified silane polymer having a high thermal stability and great surface activity.

16. The semiconductor device according to claim 1, wherein the second plastic composition comprises a polybenzoxazole, a polybenzimidazole, a polyisocyanate and/or a polyurethane having a high thermal stability and great surface activity.

17. The semiconductor device according to claim 1, wherein the second plastic composition (17) has comprises a thermal stability of above 260° C. and the softening temperature of the second plastic composition is not less than 270° C.

18. The semiconductor device according to claim 1, wherein the second plastic composition forms a closed plastic casing at least for the second semiconductor chip and the adhesive layer, the closed plastic casing having a casing thickness d_{H}, where 0.5 μm≦d_{H}≦2000 μm.

19. The semiconductor device according to claim 1, wherein:
the first semiconductor chip further comprises a power semiconductor component; and
the second semiconductor chip has comprises a sensor component.

20. The semiconductor device according to claim 1, wherein the semiconductor device further comprises a T0220 housing type.

21. The semiconductor device according to claim 1, wherein the semiconductor device further comprises a BGA housing type.

22. A method for producing a semiconductor device comprising a semiconductor chip stack, the method comprising:
producing a device carrier with contact pads disposed on a top side of the device carrier and external contact areas disposed on an underside of the device carrier;
fixing a first semiconductor chip by its rear side on a first contact pad of the device carrier;
adhesive bonding a second semiconductor chip onto the first semiconductor chip via an adhesive layer, thereby forming a semiconductor chip stack;
fitting connecting elements to the semiconductor device;
encapsulating at least edge sides of the adhesive layer and at least edge sides and a top side of the second semiconductor chip of the chip stack with a second plastic composition;
applying a first plastic housing composition, thereby embedding the encapsulated semiconductor chip stack and the connecting elements.

23. The method according to claim 22, further comprising:
producing a first semiconductor wafer with first semiconductor chips and a second semiconductor wafer with second semi-conductor chips wherein semiconductor chip positions on the top side of the semiconductor wafers comprise contact areas configured to connect to connecting elements;
separating the semiconductor wafers into individual first and second semiconductor chips;
producing a leadframe with a plurality of semiconductor device positions, each device position including the device carrier with the contact pads and the external contact areas, the device carrier further comprising a chip carrier and a plurality of leads; and
separating the leadframe into individual semiconductor components;
wherein the first plastic housing compound is applied to the leadframe, thereby embedding the encapsulated semiconductor chip stacks and the connecting elements of the device positions such that the external contact areas are left free.

24. The method according to claim 22, further comprising:
producing a first semiconductor wafer with first semiconductor chips and a second semiconductor wafer with second semi-conductor chips, wherein semiconductor chip positions on the top side of the semiconductor wafers comprise contact areas configured to connect to connecting elements;
separating the semiconductor wafers into individual first and second semiconductor chips;
producing a panel with a plurality of semiconductor device positions, each device position including the device carrier with the contact pads and the external contact areas; and
separating the panel into individual semiconductor components;
wherein the first plastic housing compound is applied to the panel, thereby embedding the encapsulated semiconductor chip stacks and connecting elements of the device positions.

25. The method according to claim 22, wherein the first semiconductor chip is fixed by its rear side on the device carrier.

26. The method according to claim 22, wherein the first semiconductor chip is fixed on the device carrier cohesively by soldering thereon, diffusion soldering and/or by alloying thereon.

27. The method according to claim 22, wherein the second semiconductor chip to be stacked is adhesively bonded by its rear side onto the top side of the first semiconductor chip.

28. The method according to claim 22, wherein fitting connecting elements to the semiconductor device includes bonding signal bonding wires onto corresponding contact areas of the semiconductor chips.

29. The method according to claim 22, wherein fitting connecting elements to the semiconductor device includes bonding aluminum bonding wires configured to supply current and bonding gold bonding wires configured to transmit signals.

30. The method according to claim 22, wherein the second plastic composition is sprayed on, spun on or applied via dipping into a plastic bath with subsequent drying and curing.

31. The method according to claim 22, wherein the second plastic composition comprises at least one of the materials selected from the group of the including: polymers, polyimides, epoxides and/or silicones.

32. The method according to claim 22, wherein the second plastic composition comprises at least one of the materials having a high thermal stability and great surface activity selected from the group including: polybenzoxazoles, polybenzimidazoles, polyisocyanates, polyurethanes, liquid crystalline polymers, phenols, unsaturated polyesters, amino resins, modified silane polymers or a mixture and/or a copolymer of said materials.

33. The semiconductor device according to claim 1, wherein edge sides of the first semiconductor chip are free of the second plastic composition.
